(19) United States
(12) Patent Application Publication
(10) Pub. No.: US 2026/0018492 A1
(43) Pub. Date: Jan. 15, 2026

(54) SEMICONDUCTOR STACKED PACKAGE AND METHOD OF MANUFACTURING THE SAME

(71) Applicant: NANYA TECHNOLOGY CORPORATION, New Taipei City (TW)

(72) Inventor: Jui-Hsiu JAO, New Taipei City (TW)

(21) Appl. No.: 18/767,957

(22) Filed: Jul. 9, 2024

(51) Int. Cl. H01L 23/48; H01L 21/768; H01L 23/00; H01L 23/498; H01L 23/528; H01L 25/065

(52) U.S. Cl. CPC H01L 23/481; H01L 21/76834; H01L 21/76877; H01L 21/76898; H01L 23/5283; H01L 25/0657; H01L 23/49816; H01L 23/49822; H01L 24/16; H01L 24/17; H01L 24/32; H01L 24/33; H01L 24/73; H01L 2224/16146; H01L 2224/16227; H01L 2224/17181; H01L 2224/32145; H01L 2224/32225; H01L 2224/33181; H01L 2224/73204

(57) ABSTRACT

The semiconductor stacked package including a semiconductor die. The semiconductor die includes a substrate, a transistor, and a through-silicon-via (TSV) structure. The transistor is over the substrate. The TSV structure penetrates the substrate and comprises a first conductive layer, a second conductive layer, and a dielectric layer. The dielectric layer is between the first conductive layer and the second conductive layer. The method of manufacturing the same includes the following steps: forming a via hole in a substrate; forming a first conductive layer in the via hole; forming a dielectric layer in the via hole and over the first conductive layer; forming a second conductive layer in the via hole and over the dielectric layer; and forming a transistor over the substrate. The first conductive layer, the dielectric layer, and the second conductive layer collectively form a through-silicon-via (TSV) structure.

### BACKGROUND

### Field of Invention

The present disclosure relates to a semiconductor stacked package and a method of manufacturing the same. More particularly, the present disclosure relates to a semiconductor device stacked package structure.

### Description of Related Art

Semiconductor devices are essential for many modern applications. With the advancement of electronic technology, semiconductor devices are becoming smaller in size while having greater functionality and greater amounts of integrated circuitry. Due to the miniaturized scale of semiconductor devices, chip-on-chip technique is now widely used for manufacturing semiconductor packages.

In one approach, using a stack of at least two chips (or dies) in a 3D package to form, for example, a memory device, it is possible to produce a product having a memory capacity which is twice as large as that obtainable through other semiconductor integration processes. In addition to the increase in memory capacity, a stacked package also provides improved mounting density and mounting area utilization efficiency. Due to such advantages, research and development of stacked package technology has accelerated.

### SUMMARY

The disclosure provides a through-silicon-via (TSV) structure in the substrate, the TSV structure comprises a dielectric layer sandwiched between two conductive layers. With such configuration, the TSV structure may function as an anti-fuse structure, which makes it a possible candidate for memory application in a semiconductor stacked package.

An aspect of the present disclosure provides a semiconductor stacked package including a semiconductor die. The semiconductor die includes a substrate, a transistor, and a through-silicon-via (TSV) structure. The transistor is over the substrate. The TSV structure penetrates the substrate and comprises a first conductive layer, a second conductive layer, and a dielectric layer. The dielectric layer is between the first conductive layer and the second conductive layer.

In some embodiments of the present disclosure, the dielectric layer has a bar-shape cross-sectional profile.

In some embodiments of the present disclosure, the first conductive layer and the second conductive layer have substantially a same width.

In some embodiments of the present disclosure, the dielectric layer comprises oxide.

In some embodiments of the present disclosure, the dielectric layer is an oxide of a material of the first conductive layer.

In some embodiments of the present disclosure, the first conductive layer and the second conductive layer have different widths.

In some embodiments of the present disclosure, the semiconductor die further includes an insulating layer surrounding the TSV structure.

In some embodiments of the present disclosure, the first conductive layer, the second conductive layer, and the dielectric layer are in contact with the insulating layer.

In some embodiments of the present disclosure, the insulating layer and the dielectric layer are made of a same material.

In some embodiments of the present disclosure, the semiconductor stacked package includes a package substrate. The semiconductor die is stacked over the package substrate. The TSV structure of the semiconductor die is electrically connected to the package substrate.

Another aspect of the present disclosure provides a method of manufacturing a semiconductor stacked package. The method includes the following steps: forming a via hole in a substrate; forming a first conductive layer in the via hole; forming a dielectric layer in the via hole and over the first conductive layer; forming a second conductive layer in the via hole and over the dielectric layer; and forming a transistor over the substrate. The first conductive layer, the dielectric layer, and the second conductive layer collectively form a through-silicon-via (TSV) structure.

In some embodiments of the present disclosure, forming the dielectric layer comprises depositing a dielectric material lining the via hole.

In some embodiments of the present disclosure, forming the dielectric layer comprises oxidizing an exposed surface of the first conductive layer through the via hole.

In some embodiments of the present disclosure, the method further includes forming an insulating layer lining the via hole prior to forming the first conductive layer.

In some embodiments of the present disclosure, the method further includes performing a grinding process on a backside of the substrate until the first conductive layer is exposed.

In some embodiments of the present disclosure, forming the first conductive layer includes: depositing a conductive material overfilling the via hole; performing a polishing process on the conductive material until the substrate is exposed; and etching back the conductive material to lower a surface of the conductive material.

In some embodiments of the present disclosure, the method further includes forming an interconnect structure electrically connecting the TSV structure and the transistor.

In some embodiments of the present disclosure, the method further includes forming bumps over the interconnect structure; and bonding the bumps to a package substrate.

In some embodiments of the present disclosure, the method further includes stacking a semiconductor die over the substrate. The semiconductor die is electrically connected to the TSV structure.

In some embodiments of the present disclosure, the method further includes breaking the dielectric layer by applying a bias to the first conductive layer or the second conductive layer after forming the transistor over the substrate. A conductive path is formed between the first conductive layer and the second conductive layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a cross-sectional view of a semiconductor stacked package in accordance with some embodiments of the present disclosure.

FIG. 2A illustrates an enlarged view of a semiconductor device at portion A of the semiconductor stacked package shown in FIG. 1.

FIG. 2B illustrates an enlarged view of a semiconductor device in accordance with some embodiments of the present disclosure.

FIGS. 3A to 3O illustrate a method in various stages of manufacturing a semiconductor staked structure in accordance with some embodiments of the present disclosure.

FIGS. 4A to 4D illustrate a method in various stages of manufacturing a semiconductor staked structure in accordance with some embodiments of the present disclosure.

FIGS. 5A and 5B illustrate operating a TSV structure of a semiconductor staked structure at different conditions in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

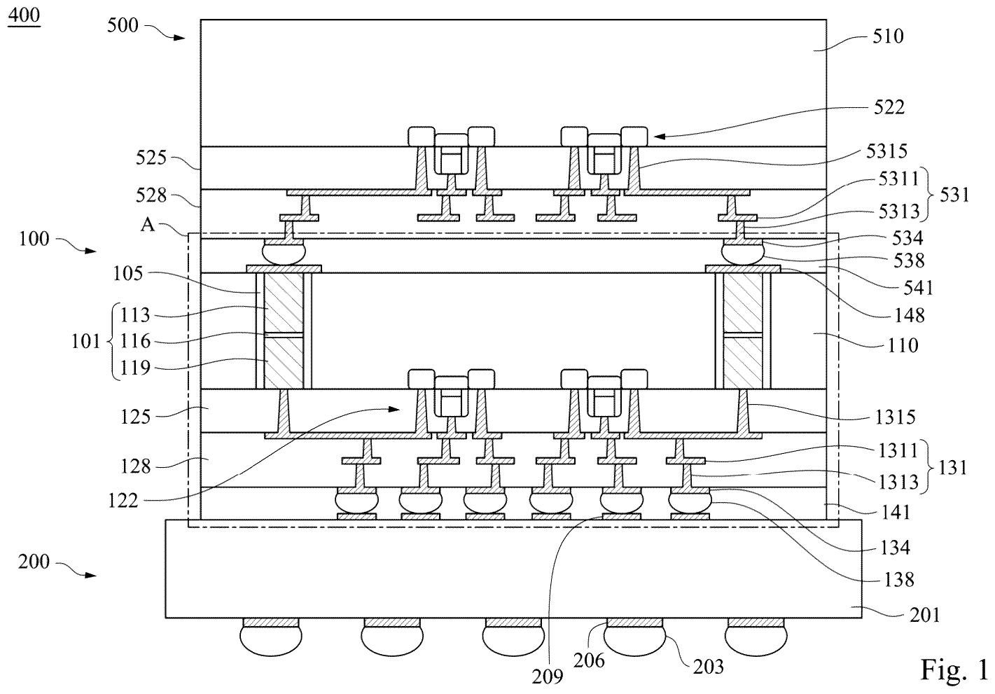

Referring to FIG. 1, FIG. 1 is a schematic cross-sectional view of a semiconductor stacked package according to one embodiment of the present disclosure. The semiconductor stacked package 400 may include a semiconductor die 500, a semiconductor die 100, and a package substrate 200. The semiconductor die 100 is stacked over the package substrate 200, and is electrically connected with the package substrate 200 through the respective connection bumps 138. The semiconductor die 500 is stacked over the semiconductor die 100, and is electrically connected with the semiconductor die 100 through the respective connection bumps 538. In some embodiments, the space between the semiconductor die 100 and the package substrate 200 and the space between the semiconductor die 100 and the semiconductor die 500 may be filled with underfills 141 and 541, respectively. The underfills 141 and 541 surround the corresponding connection bumps 138 and 538 and may serve as protective layers of the connection bumps 138 and 538.

With respect to the package substrate 200, in some embodiments, the package substrate 200 may include, for example, a printed circuit board. For example, the package substrate 200 may include a multi-layered printed circuit board. The package substrate 200 may include a substrate base 201, lower substrate lower conductive pads 206 arranged on a lower surface of the substrate base 201, upper substrate conductive pads 209 arranged on an upper surface of the substrate base 201, and external connection bumps 203 arranged on the lower substrate lower conductive pads 206.

In some embodiments, the substrate base 201 may include at least one material selected from phenol resins, epoxy resins, and polyimide. The external connection bumps 203 are configured to electrically connect an external device with the semiconductor stacked package 400. The external connection bumps 203 may include, for example, a solder ball.

As illustrated in FIG. 1, shown there are two semiconductor dies vertically stacked on the package substrate 200. However, the present disclosure is not limited thereto. For example, three or more semiconductor dies may be stacked on the package substrate 200 in a vertical direction.

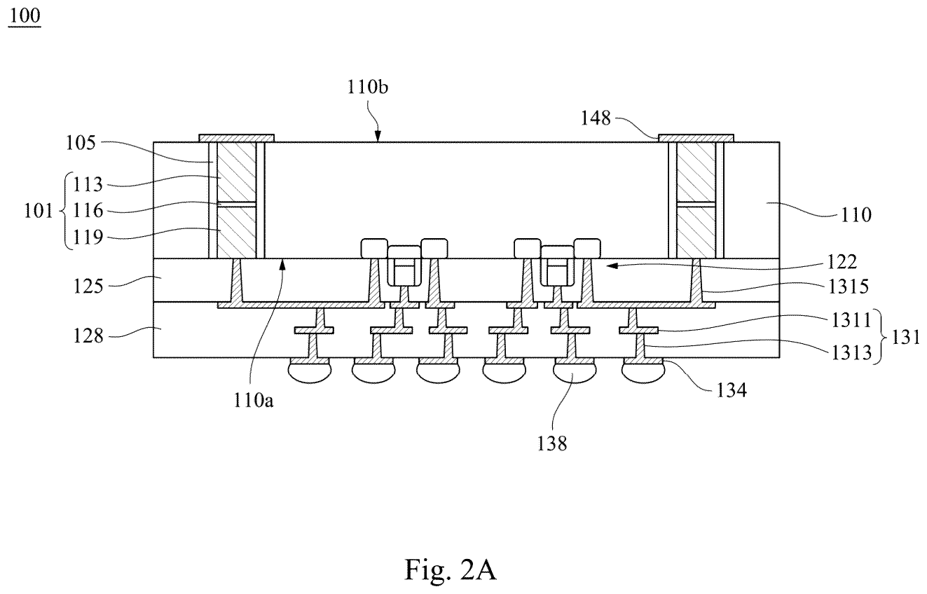

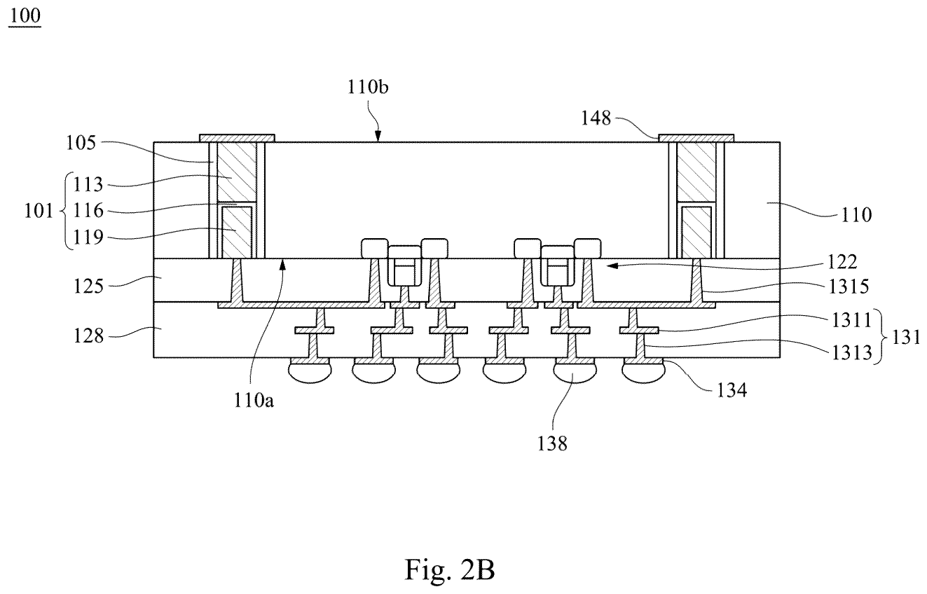

Reference is made to FIGS. 1 and 2A, in which FIG. 2A is an enlarged view of the semiconductor die 100 at portion A of the semiconductor stacked package 400 shown in FIG. 1. The semiconductor die 100 may include a substrate 110, through-silicon-via (TSV) structures 101, transistors 122, an interlayer dielectric (ILD) layer 125, and an inter-metal dielectric (IMD) layer 128 over the ILD layer 125 . . . . The TSV structures 101 may be arranged in the substrate 110 and may penetrate the substrate 110. The transistors 122 may be arranged on a surface 100a of the substrate 110 and be covered by the ILD layer 125. An IMD layer 128 is arranged over the ILD layer 125.

With respect to the TSV structures 101, each of the TSV structures 101 may include a first conductive layer 113, a second conductive layer 119, and a dielectric layer 116 sandwiched between the first conductive layer 113 and the second conductive layer 119. The dielectric layer 116 may include a bar-shape cross-sectional profile. The first conductive layer 113 and the second conductive layer 119 may have substantially a same width. Insulating layers 105 may surround the respective TSV structures 101. For example, the insulating layer 105 may extend along opposite sidewalls of the TSV structure 101, and may separate the TSV structure 101 from the substrate 110.

In some embodiments, the first conductive layer 113 and the second conductive layer 119 may include metal, such as copper (Cu), or other suitable conductive material. In some embodiments, the insulating layers 105 may include dielectric materials, such as silicon oxide, silicon nitride, or the like. The dielectric layer 116 may include oxide. In some embodiments, the dielectric layer 116 may include silicon oxide. In other embodiments, the dielectric layer 116 may be an oxide of the material of the first conductive layer 113. In some embodiments, the insulating layer 105 and the dielectric layer 116 may be made of a same material, such as silicon oxide.

In some embodiments, the substrate 110 may include a semiconductor substrate. In some embodiments, the substrate 110 may include, for example, silicon (Si). Alternatively, the substrate 110 may include a semiconductor element, such as germanium (Ge), or a compound semiconductor, such as silicon carbide (SiC), gallium arsenide (GaAs), indium arsenide (InAs), and indium phosphide (InP). In some embodiments, the substrate 110 may include a conductive region, for example, a well doped with impurities or a structure doped with impurities. Also, the substrate 110 may have various device isolation structures, such as a shallow trench isolation (STI) structure.

In some embodiments, the transistors 122 may include, for example, a metal-oxide-semiconductor field-effect transistor (MOSFET). For example, the transistors 122 may include an n-type metal-oxide-semiconductor (NMOS), a p-type metal-oxide-semiconductor (PMOS), or the like. Other devices, such as a system large scale integration (LSI), an image sensor, such as a complementary metal-oxide-semiconductor a (CMOS) imaging sensor (CIS), micro-electromechanical system (MEMS), an active device, a passive device, or the like, may also be disposed on the substrate 110.

In the embodiments of FIG. 2A, each of the transistors 122 may include a gate structure over the substrate 110, and source/drain regions in the substrate 110 and on opposite sides of the gate structure. Gate spacers may be disposed on opposite sidewalls of the gate structure.

In some embodiments, the ILD layer 125 may include a dielectric material and conductive vias 1315 (as well as referred first conductive vias). The dielectric material may be silicon oxide, silicon nitride, silicon oxynitride, PSG, BPSG, low-k dielectric material, and/or other applicable dielectric material. In some embodiments, the conductive vias 1315 may include tungsten (W), copper (Cu), aluminum (Al), or the like.

In some embodiments, the IMD layer 128 may include interconnect structure 131 disposed therein. For example, interconnect structures 131 may include conductive lines 1311 and conductive vias 1313 (as well as referred second conductive vias). In some embodiments, the IMD layer 128 may include dielectric material, such as silicon oxide, silicon nitride, silicon oxynitride, PSG, BPSG, low-k dielectric material, and/or other applicable dielectric material. In some embodiments, the conductive lines 1311 and the conductive vias 1313 may include tungsten (W), copper (Cu), aluminum (Al), or the like.

In some embodiments, the semiconductor die 100 may further include lower conductive pads 134 extending along a surface of the IMD layer 128 and electrically connected with the interconnect structure 131. The connection bumps 138 may be electrically connected to the lower conductive pads 134. The semiconductor die 100 further includes upper conductive pads 148 extending along a surface 110b of the substrate 110, and in contact with the first conductive layer 113 of the TSV structure 101. In some embodiments, the lower conductive pads 134 and the upper conductive pads 148 may include tungsten (W), copper (Cu), aluminum (Al), or the like.

With respect to the semiconductor die 500, the structure of the semiconductor die 500 may be similar to the structure of the semiconductor die 100. For example, the semiconductor die 500 may include a substrate 510, a transistors 522 over the substrate 510, and ILD layer 525 over the substrate 510 and covering the transistors 522, conductive vias 5315 in the ILD layer 525 and electrically connected with the transistors 522, an IMD layer 528 over the ILD layer 525, an interconnect structure 531 in the IMD layer 528 and electrically connected with the conductive vias 5315 The semiconductor die 500 further includes conductive pads 534 extending along a surface of the IMD layer 528 and electrically connected with the interconnect structure 531. The connection bumps 538 are in contact with the conductive pads 534.

Referring to FIG. 2B, FIG. 2B is an enlarged view of a semiconductor die 100 in accordance with another embodiment of the present disclosure. It is noted that some elements of FIG. 2B are similar to those described with respect to FIG. 2A, such elements are labeled the same, and relevant details will not be repeated for brevity. The difference between FIG. 2A and FIG. 2B is that the dielectric layer 116 may line the bottom surface and opposite sidewalls of the second conductive layer 119 of the TSV structure 101. That is, the dielectric layer 116 may include a U-shape cross-sectional profile. In some embodiments, the first conductive layer 113 may be in contact with the insulating layer 105, while the second conductive layer 119 may be spaced apart from the insulating layer 105 through the dielectric layer 116. In some embodiments, the first conductive layer and the second conductive layer may have different widths. For example, the width of the first conductive layer 113 may be wider than the width of the second conductive layer 119.

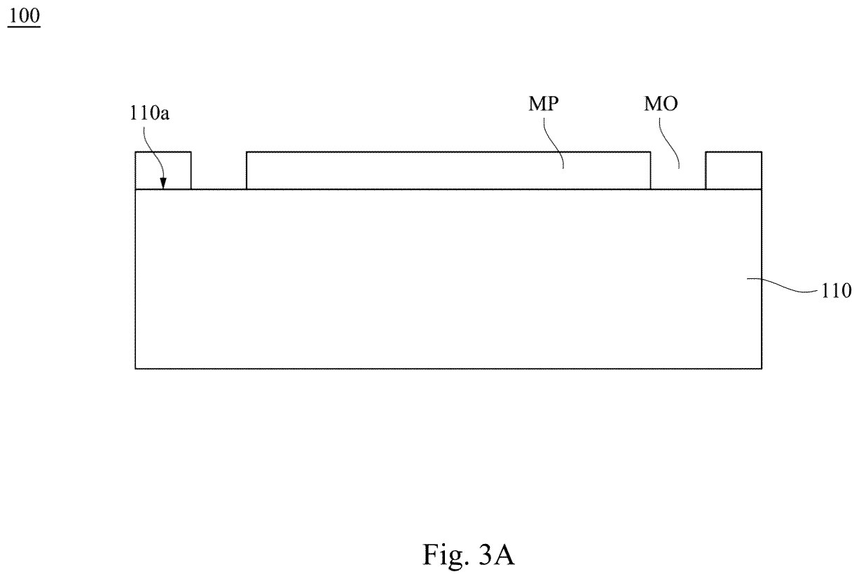

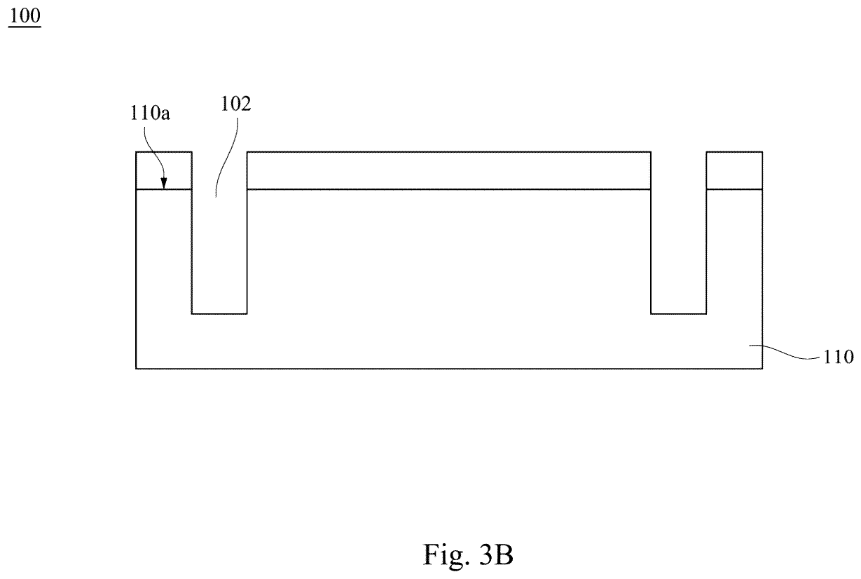

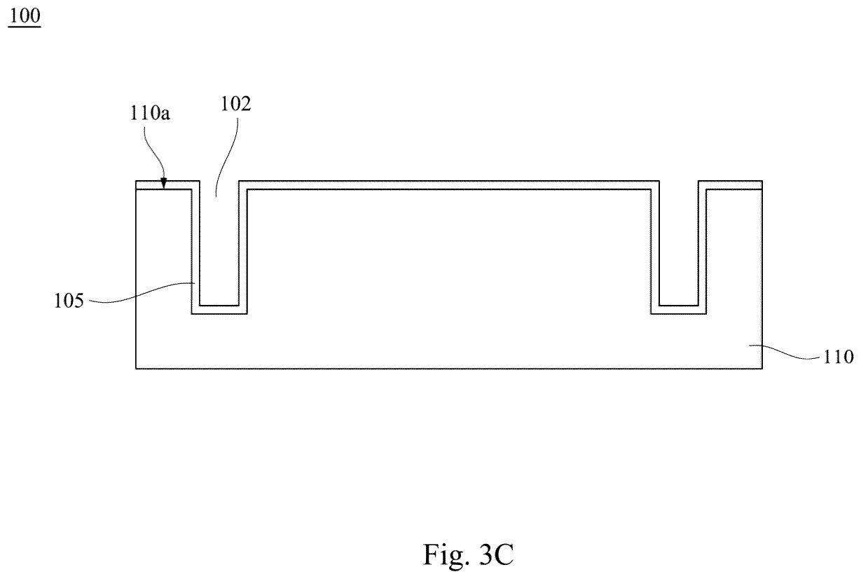

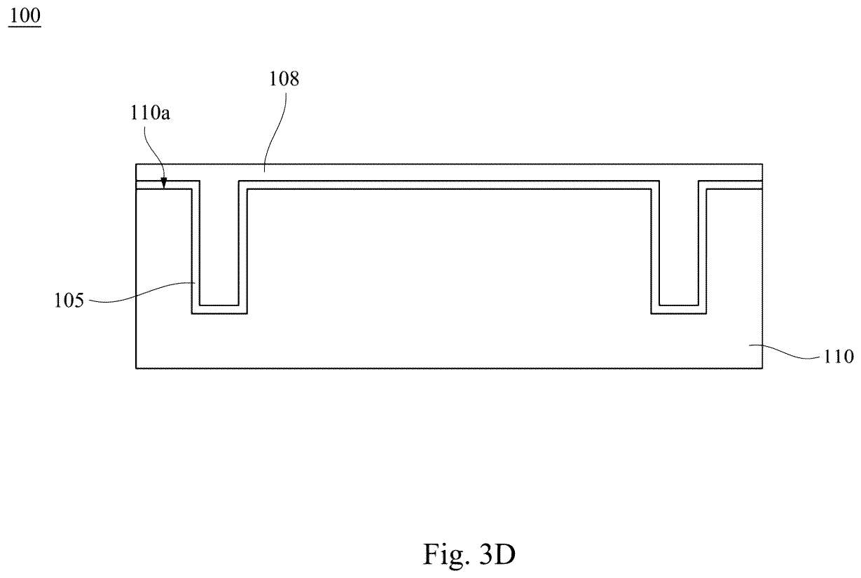

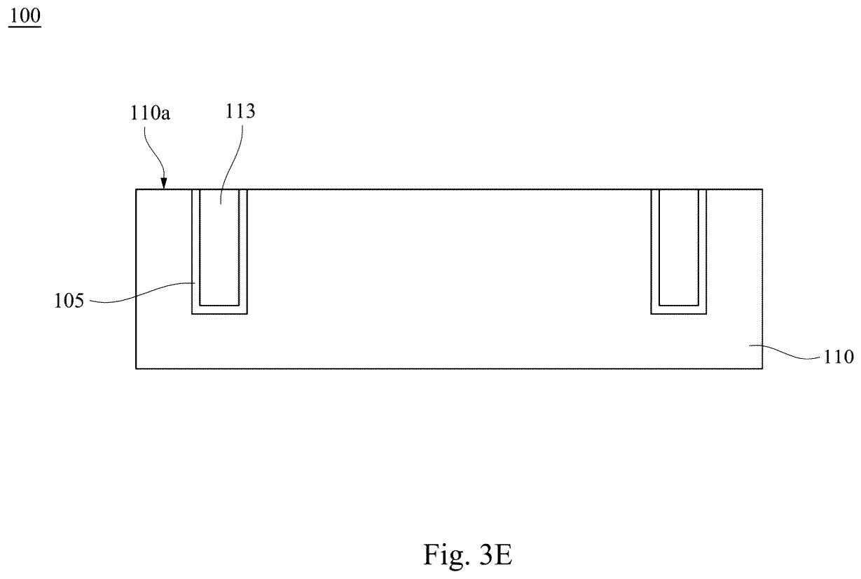

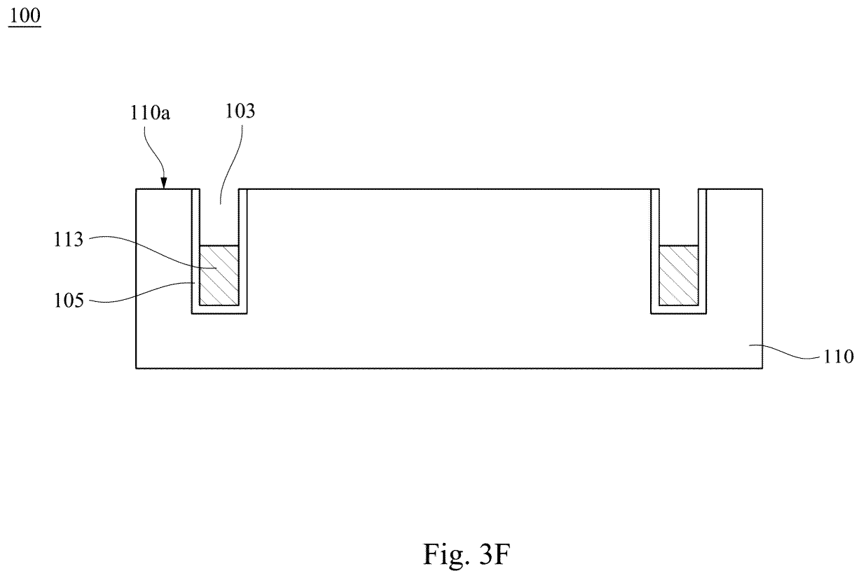

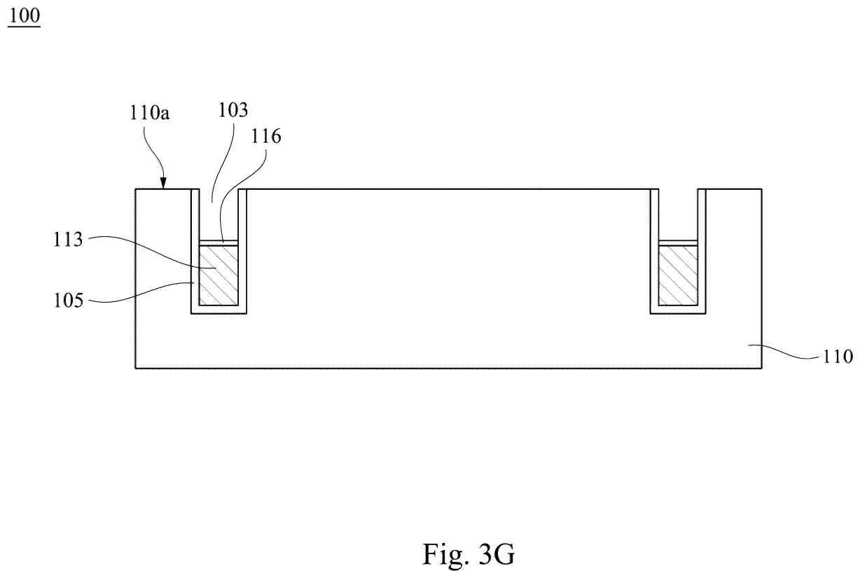

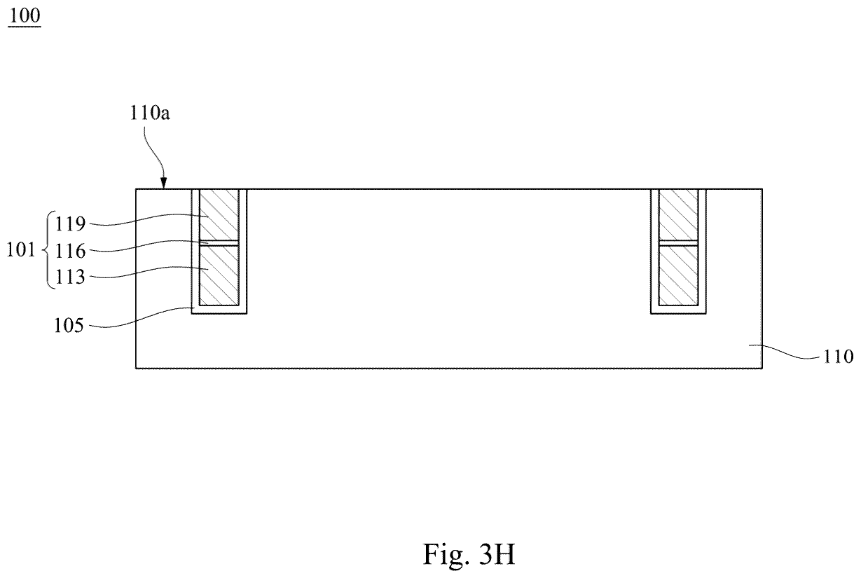

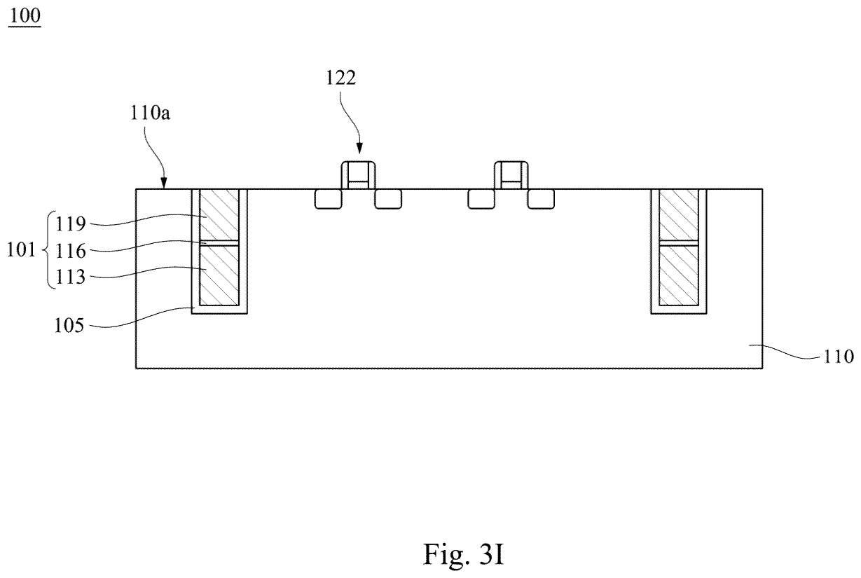

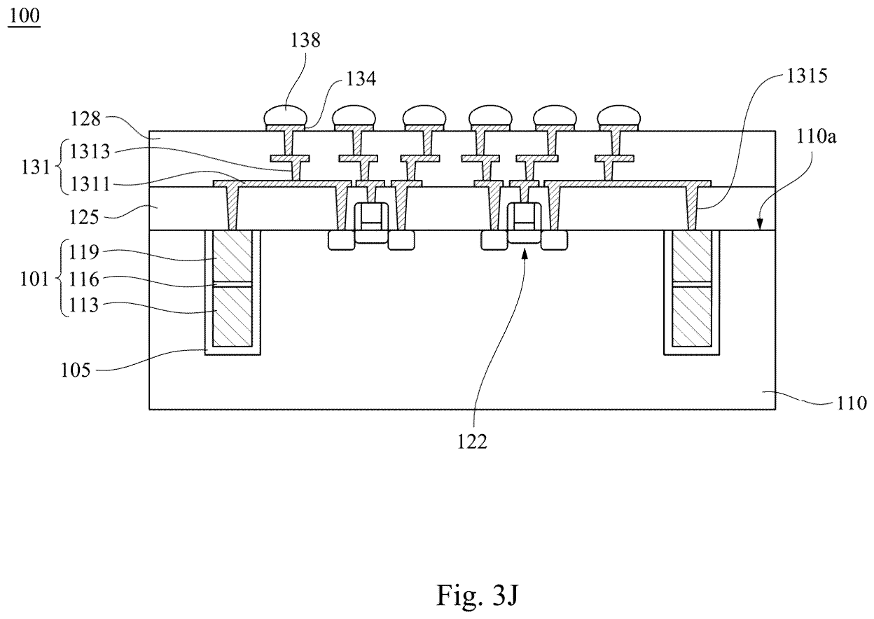

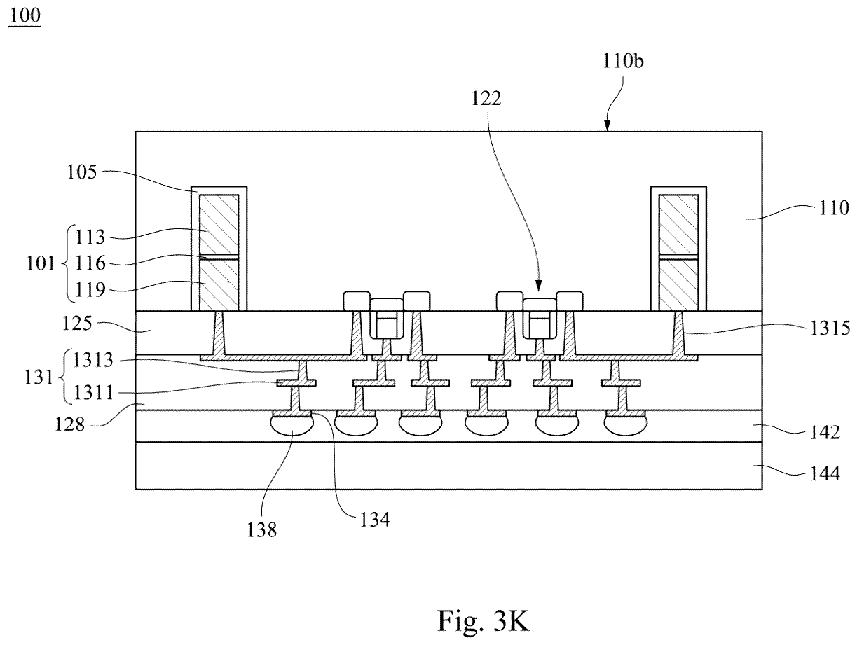

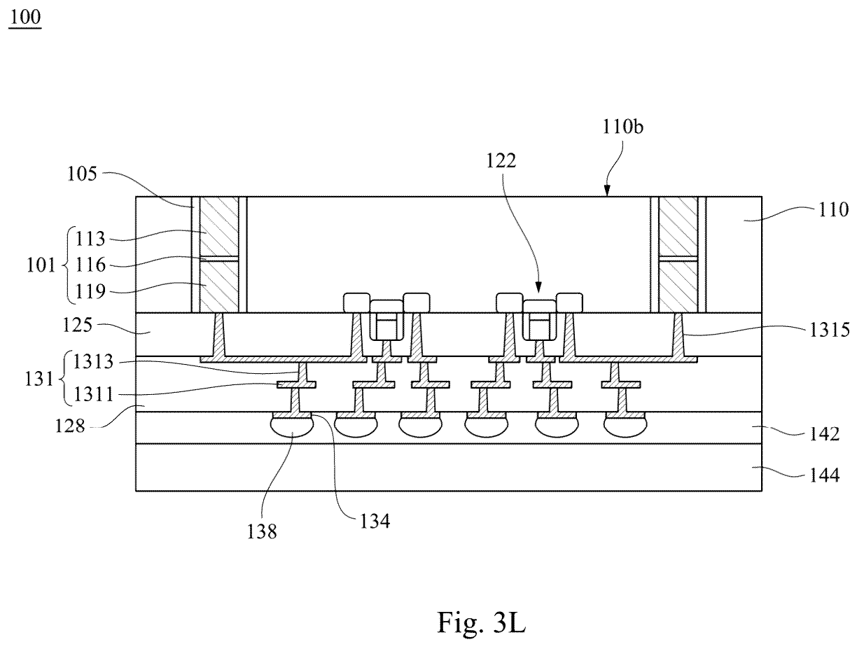

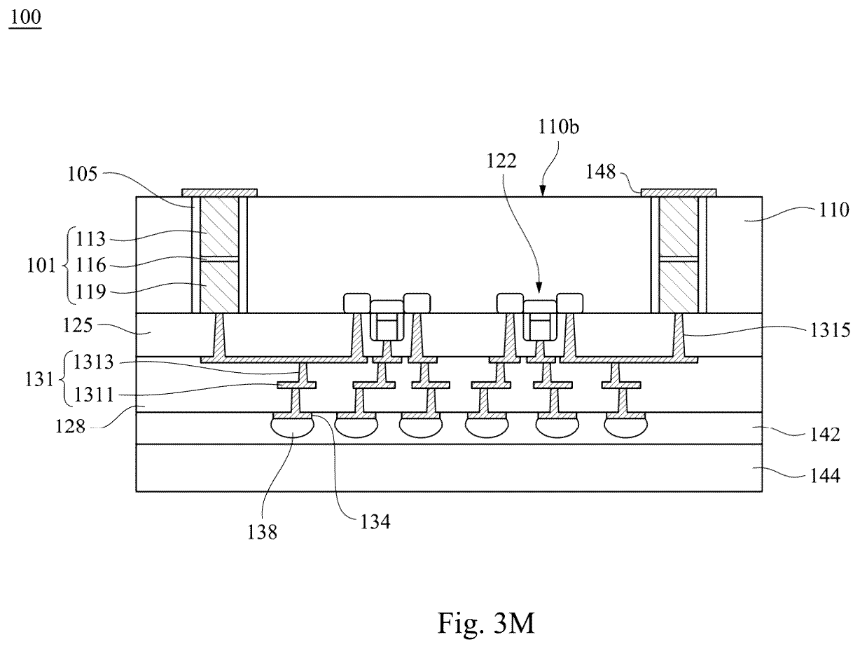

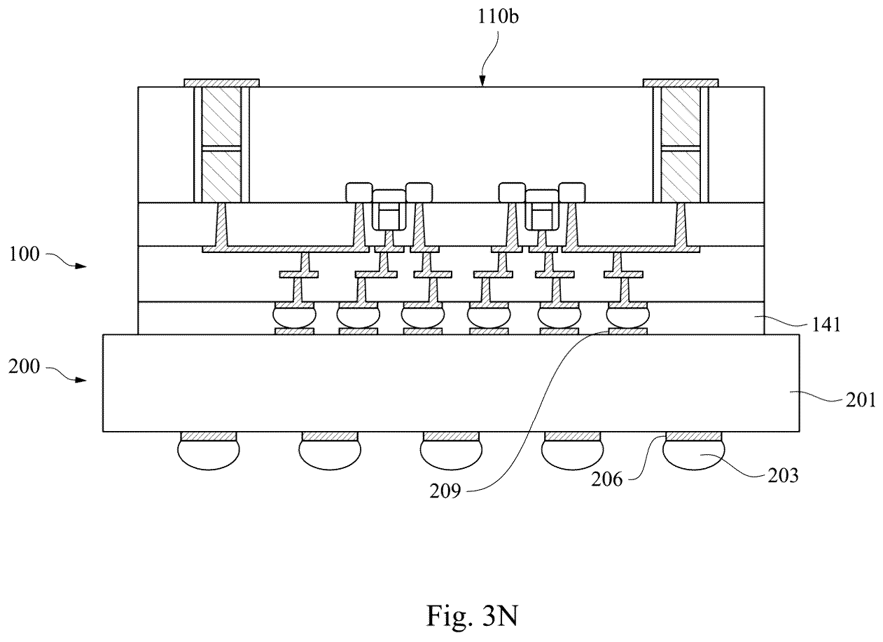

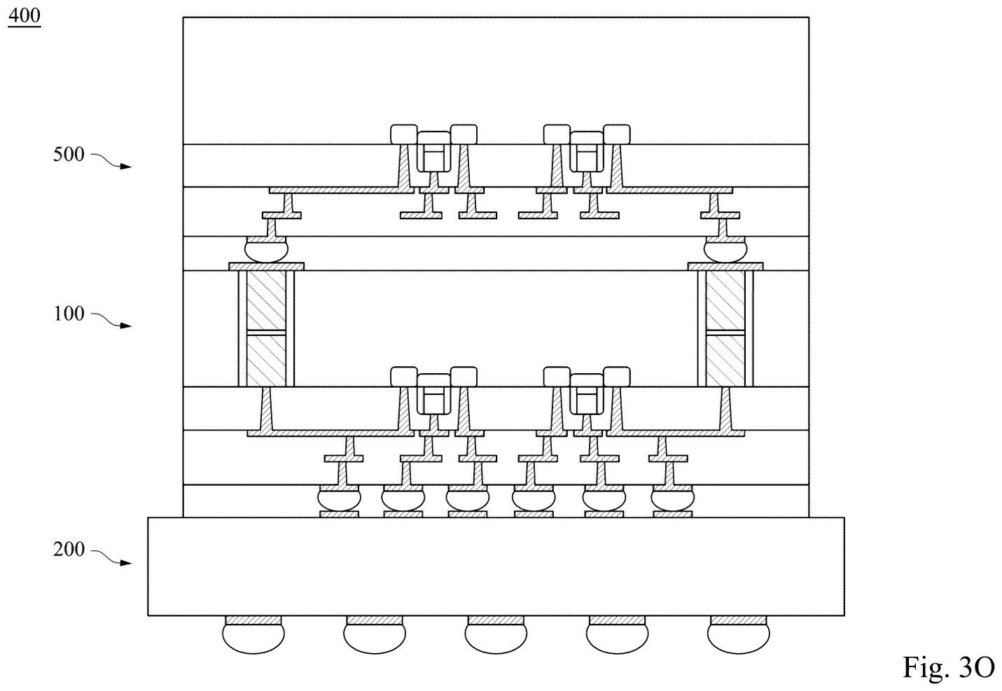

Referring to FIG. 3A, a patterned mask MP may be formed on a surface 110a of a substrate 110. The patterned mask MP may include mask openings MO exposing portions of the substrate 110. The patterned mask MP may include, for example, a photoresist. The mask openings MO may be formed in the patterned mask MP using suitable photolithography process.

Referring to FIG. 3B, an etching process is performed to remove portions of the substrate 110 through the mask openings MO of the patterned mask MP, so as to form via holes 102 in the substrate 110. It is described that the via holes 102 are formed by an etching process, while the disclosure is not limited thereto. In other embodiments, the via holes 102 may be formed by a laser drilling process.

Referring to FIG. 3C, after the via holes 102 are formed, the patterned mask MP is removed. Then, an insulating layer 105 is formed lining the substrate 110 and the via holes 102. In greater detail, the insulating layer 105 may cover inner sidewalls and bottom surface of each via hole 102. In some embodiments, the insulating layer 105 may be formed using suitable deposition process, such as chemical vapor deposition (CVD), atomic layer deposition (ALD), or the like.

Referring to FIG. 3D, a conductive material layer 108 may be formed over the substrate 110 and filling the via holes 102. The conductive material layer 108 can be formed using suitable deposition process, such as physical vapor deposition (PVD), chemical vapor deposition (CVD), atomic layer deposition (ALD), or the like.

Referring to FIG. 3E, a polishing process, such as a chemical mechanical polishing (CMP), may be performed on the structure of FIG. 3D to remove excess materials of the conductive material layer 108 and the insulating layer 105 until the substrate 110 is exposed. After the polishing process is complete, the remaining portions of the conductive material layer 108 in the via holes 102 may be referred to as the first conductive layers 113.

Referring to FIG. 3F, an etching back process is performed to lower top surfaces of the first conductive layers 113, so as to form via holes 103 in the substrate 110 and over the first conductive layers 113. The etching back process may include dry etch, wet etch, or combinations thereof.

Referring to FIG. 3G, dielectric layers 116 are formed in the via holes 103 and over the respective first conductive layers 113. In some embodiments, the dielectric layers 116 may be formed using suitable deposition process, such as physical vapor deposition (PVD), chemical vapor deposition (CVD), atomic layer deposition (ALD), or the like. In other embodiments, the dielectric layers 116 may be formed by oxidizing the first conductive layers 113 through the exposed surfaces of the first conductive layers 113. In such condition, the dielectric layer 116 may be an oxide of the material of the first conductive layer 113. The dielectric layer 116 may include a bar-shape cross-sectional profile in the via holes 103.

Referring to FIG. 3H, second conductive layers 119 are formed in the via holes 103 and over the respective dielectric layers 116. The second conductive layers 119 may be formed in a similar way as forming the first conductive layers 113, for example, a conductive material layer may be formed filling the via holes 103, followed by a polishing process to remove excess conductive material layer until the substrate 110 is exposed. Then, TSV structures 101 are formed in the substrate 110. The TSV structure 101 may include the first conductive layer 113, the dielectric layer 116, and the second conductive layer 119. The first conductive layer and the second conductive layer may have substantially a same width.

Referring to FIG. 3I, transistors 122 may be formed on the substrate 110. The transistors 122 may be formed using suitable process known in the art, and thus relevant details are omitted for brevity.

Referring to FIG. 3J, an interlayer dielectric (ILD) layer 125 is formed over the substrate 110 and covering the transistors 122, and conductive vias 1315 are formed in the ILD layer 125. Then, an inter-metal dielectric (IMD) layer 128 is formed over the ILD layer 125, and an interconnect structure 131 is formed in the IMD layer 128. Afterwards, lower conductive pads 134 are formed over the IMD layer 128 and electrically connected to the interconnect structure 131, and connection bumps 138 are formed over the lower conductive pads 134.

Referring to FIG. 3K, the substrate 110 is then turned upside down (e.g., flipped over by 180 degrees) and adhered to a carrier substrate 144 through an adhesive tape 142. In greater detail, the connection bumps 138 are adhered to the adhesive tape 142. In some embodiments, the adhesive tape 142 may be a UV tape that may be easily detached by ultra-violet (UV) irradiation.

Referring to FIG. 3L, a grinding process is performed to thin down the substrate 110 until the TSV structures 101 are exposed. In greater detail, the surfaces of the first conductive layer 113 of the TSV structure 101 may be exposed through the surface 110b of the substrate 110 after the grinding process is complete.

Referring to FIG. 3M, upper conductive pads 148 are formed over the surface 110b of the substrate 110 and are connected to the TSV structures 101. In some embodiments, after the upper conductive pads 148 are formed, a semiconductor die 100 is formed.

Referring to FIG. 3N, the semiconductor die 100 is detached from the carrier substrate 144. Afterwards, the semiconductor die 100 may be stacked on a package substrate 200. In some embodiments, the semiconductor die 100 may be stacked on the package substrate 200 by bonding the connection bumps 138 of the semiconductor die 100 to the corresponding upper conductive pads 209 on the package substrate 200. Underfills 141 are then formed filling the space between the semiconductor die 100 and the package substrate 200.

Referring to FIG. 3O, a semiconductor die 500 is stacked over the semiconductor die 100. In some embodiments, the semiconductor die 500 may be stacked on the semiconductor die 100 by bonding the connection bumps 538 of the semiconductor die 500 to the corresponding upper conductive pads 148 on the semiconductor die 100. Underfills 141 are then formed filling the space between the semiconductor die 500 and the semiconductor die 100.

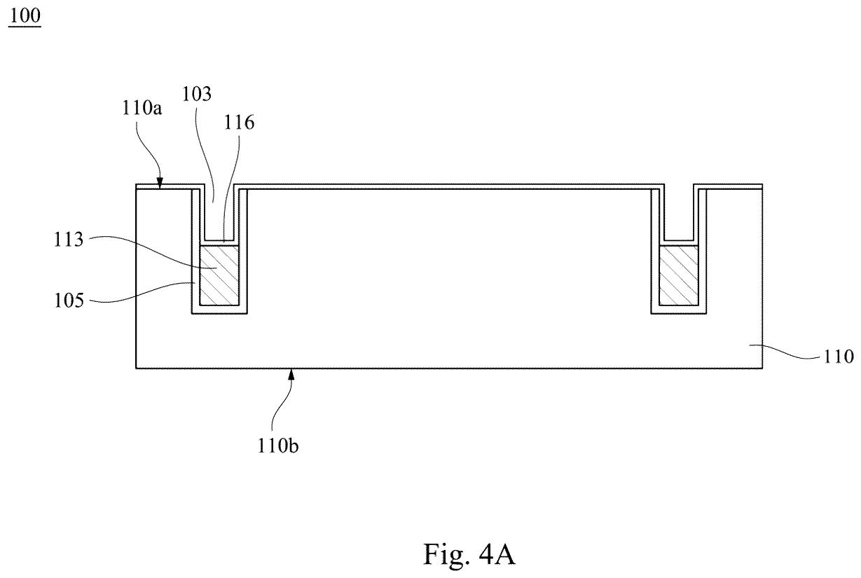

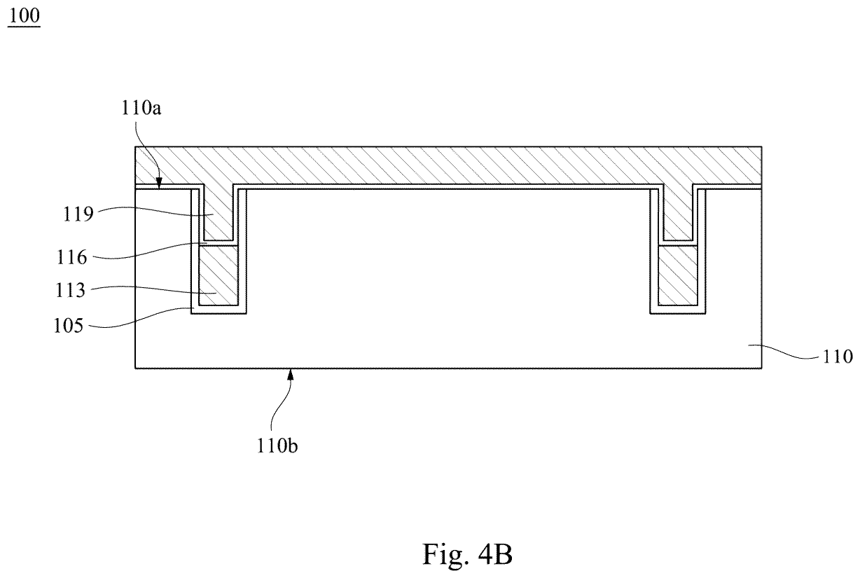

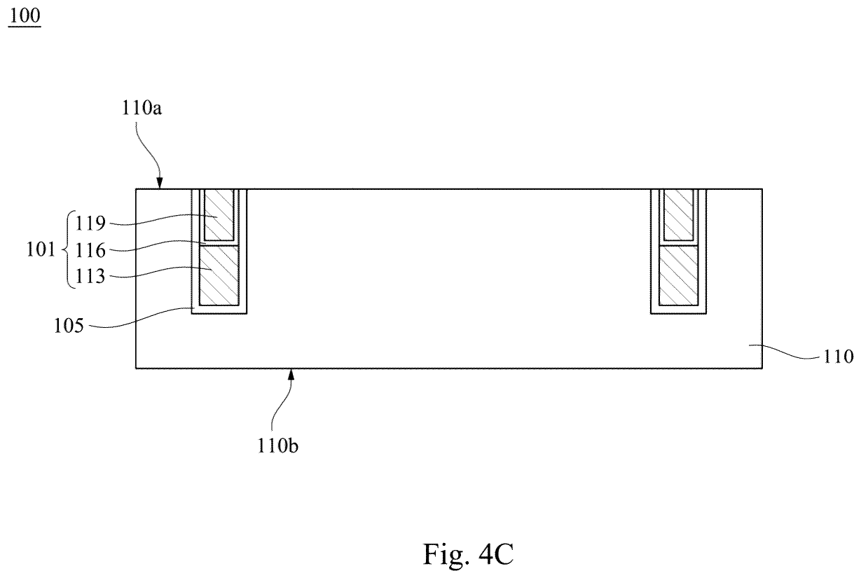

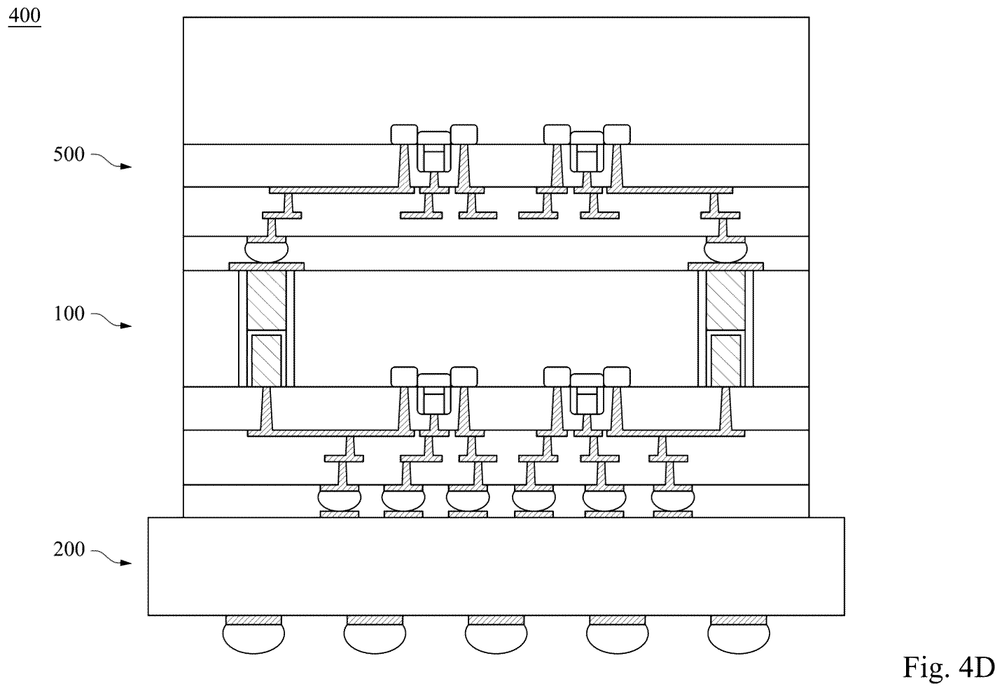

Referring to FIG. 4A, dielectric layers 116 are formed in the via holes 103 and over the respective first conductive layers 113 and the surface 110a of the substrate 110. In some embodiments, the dielectric layers 116 may be formed using suitable deposition process, such as physical vapor deposition (PVD), chemical vapor deposition (CVD), atomic layer deposition (ALD), or the like. The dielectric layer 116 may include a U-shape cross-sectional profile in the via holes 103.

Referring to FIG. 4B, second conductive layer 119 are formed in the via holes 103 and over the dielectric layer 116. The second conductive layers 119 may be formed using suitable deposition process, such as physical vapor deposition (PVD), chemical vapor deposition (CVD), atomic layer deposition (ALD), or the like.

Referring to FIG. 4C, a polishing process, such as a chemical mechanical polishing (CMP), may be performed on the structure of FIG. 4B to remove excess materials of the second conductive layer 119 and the dielectric layer 116 until the substrate 110 is exposed. After the polishing process is complete, TSV structures 101 are formed in the substrate 110. The TSV structure 101 may include the first conductive layer 113, the dielectric layer 116, and the second conductive layer 119. In some embodiments, the first conductive layer and the second conductive layer may have different widths.

Referring to FIG. 4D, a semiconductor die 100-1 is stacked over the semiconductor die 100. In some embodiments, the semiconductor die 100-1 may be stacked on the semiconductor die 100 by bonding the connection bumps 538 of the semiconductor die 100-1 to the corresponding upper conductive pads 148 on the semiconductor die 100. Underfills 141 are then formed filling the space between the semiconductor die 100-1 and the semiconductor die 100.

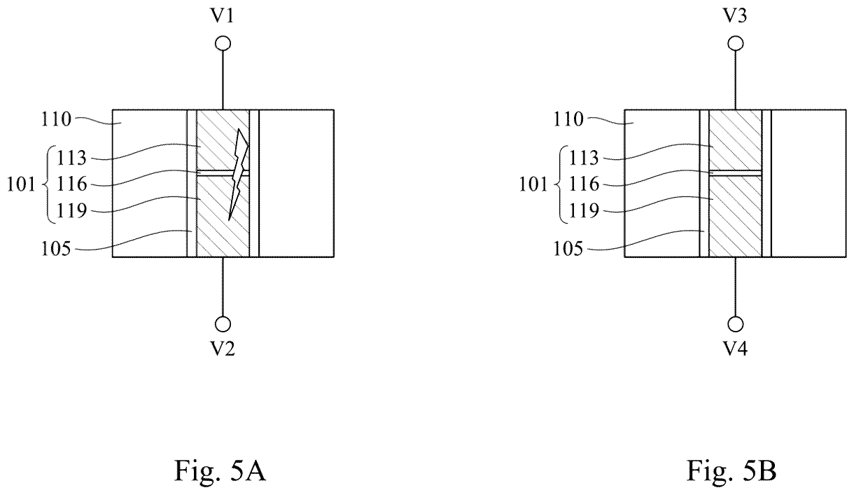

FIGS. 5A and 5B illustrate operating the TSV structure 101 of the semiconductor stacked package 400 of FIG. 1 at different conditions. In some embodiments, the TSV structure 101 may function as an anti-fuse structure, and FIGS. 5A and 5B illustrate different programing operations to the TSV structure 101. It is noted that some elements of FIG. 1 are omitted herein for simplicity.

In FIG. 5A, in a first condition, a voltage V1 and a voltage V2 are applied to opposite ends of the TSV structure 101. For example, the voltage V1 is applied to the first conductive layer 113, and the voltage V2 is applied to the second conductive layer 119. In some embodiments, the voltage V1 may be applied to the first conductive layer 113 through the semiconductor die 500 of FIG. 1, and the voltage V2 may be applied to the second conductive layer 119 through the package substrate 200 of FIG. 1. In some embodiments, the voltage V1 may be at a high voltage level, and the voltage V2 may be a low voltage level (e.g., ground voltage). In other embodiments, the voltage V2 may be at a high voltage level, and the voltage V1 may be a low voltage level (e.g., ground voltage).

In the embodiments of FIG. 5A, the voltage difference between the voltage V1 and voltage V2 is sufficiently large to destroy the dielectric layer 116 (e.g., broken down). When the dielectric layer 116 is destroyed, a current path is created between the first conductive layer 113 and the second conductive layer 119. The resulting circuit can be regarded as having a resistance between the first conductive layer 113 and the second conductive layer 119.

In FIG. 5B, in a second condition, a voltage V3 and a voltage V4 are applied to opposite ends of the TSV structure 101. For example, the voltage V3 is applied to the first conductive layer 113, and the voltage V4 is applied to the second conductive layer 119. Similarly, the voltage V3 may be applied to the first conductive layer 113 through the semiconductor die 500 of FIG. 1, and the voltage V4 may be applied to the second conductive layer 119 through the package substrate 200 of FIG. 1. In some embodiments, the voltage V3 may be at a high voltage level, and the voltage V4 may be a low voltage level (e.g., ground voltage). In other embodiments, the voltage V4 may be at a high voltage level, and the voltage V3 may be a low voltage level (e.g., ground voltage).

Different from FIG. 5A, in the embodiments of FIG. 5B, the voltage difference between the voltage V3 and voltage V4 may not be large enough to destroy the dielectric layer 116. As a result, the first conductive layer 113 and the second conductive layer 119 remain electrically isolated from each other through the dielectric layer 116.

After the program operation of FIG. 5A is complete, current may flow through the TSV structure 101, because the dielectric layer 116 has been destroyed. Accordingly, data ‘1’ can be determined. On the other hand, after the program operation of FIG. 5B is complete, the dielectric layer 116 may kept substantially intact, and current may not flow through the TSV structure 101. Accordingly, data ‘0’ can be determined. That is, if the dielectric layer 116 is broken down, the TSV structure 101 may have a logic level of ‘1’; if the dielectric layer 116 is not broken down, the TSV structure 101 may have a logic level of ‘0’. Based on the above discussion, it can be seen that the TSV structure 101 may function as an anti-fuse structure, which makes it a possible candidate for memory application in the semiconductor stacked package 400.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor stacked package, comprising:
a semiconductor die, comprising:
a substrate;
a transistor over the substrate; and
a through-silicon-via (TSV) structure penetrating the substrate and comprising a first conductive layer, a second conductive layer, and a dielectric layer between the first conductive layer and the second conductive layer.

2. The semiconductor stacked package of claim 1, wherein the dielectric layer has a bar-shape cross-sectional profile.

3. The semiconductor stacked package of claim 1, wherein the first conductive layer and the second conductive layer have substantially a same width.

4. The semiconductor stacked package of claim 1, wherein the dielectric layer comprises oxide.

5. The semiconductor stacked package of claim 1, wherein the dielectric layer is an oxide of a material of the first conductive layer.

6. The semiconductor stacked package of claim 1, wherein the first conductive layer and the second conductive layer have different widths.

7. The semiconductor stacked package of claim 1, wherein the semiconductor die further comprising an insulating layer surrounding the TSV structure.

8. The semiconductor stacked package of claim 7, wherein the first conductive layer, the second conductive layer, and the dielectric layer are in contact with the insulating layer.

9. The semiconductor stacked package of claim 8, wherein the insulating layer and the dielectric layer are made of a same material.

10. The semiconductor stacked package of claim 1, further comprising:
a package substrate, wherein the semiconductor die is stacked over the package substrate, and the TSV structure of the semiconductor die is electrically connected to the package substrate.

11. A method of manufacturing a semiconductor stacked package, comprising:
forming a via hole in a substrate;
forming a first conductive layer in the via hole;
forming a dielectric layer in the via hole and over the first conductive layer;
forming a second conductive layer in the via hole and over the dielectric layer, wherein the first conductive layer, the dielectric layer, and the second conductive layer collectively form a through-silicon-via (TSV) structure; and
forming a transistor over the substrate.

12. The method of claim 11, wherein forming the dielectric layer comprises depositing a dielectric material lining the via hole.

13. The method of claim 11, wherein forming the dielectric layer comprises oxidizing an exposed surface of the first conductive layer through the via hole.

14. The method of claim 11, wherein prior to forming the first conductive layer, forming an insulating layer lining the via hole.

15. The method of claim 11, further comprising performing a grinding process on a backside of the substrate until the first conductive layer is exposed.

16. The method of claim 11, wherein forming the first conductive layer comprises:
depositing a conductive material overfilling the via hole;
performing a polishing process on the conductive material until the substrate is exposed; and
etching back the conductive material to lower a surface of the conductive material.

17. The method of claim 11, further comprising forming an interconnect structure electrically connecting the TSV structure and the transistor.

18. The method of claim 17, further comprising:
forming bumps over the interconnect structure; and
bonding the bumps to a package substrate.

19. The method of claim 11, further comprising stacking a semiconductor die over the substrate, such that the semiconductor die is electrically connected to the TSV structure.

20. The method of claim 11, further comprising after forming the transistor over the substrate, breaking the dielectric layer by applying a voltage to the first conductive layer or the second conductive layer, such that a conductive path is formed between the first conductive layer and the second conductive layer.
